(19) United States
(12) Patent Application Publication
(10) Pub. No.: US 2008/0314554 A1
(43) Pub. Date: Dec. 25, 2008

(54) HEAT DISSIPATION DEVICE WITH A HEAT PIPE

(75) Inventor: DONG-YUN LI, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Taipei Hsien (TW)

(21) Appl. No.: 11/764,989

(22) Filed: Jun. 19, 2007

(51) Int. Cl. F28D 15/02; H05K 7/20

(52) U.S. Cl. 165/80.3; 165/104.33; 361/700

(57) ABSTRACT

A heat dissipation device with a heat pipe includes a base for thermally engaging with an electronic device, a first fin assembly and a second fin assembly arranged on the base, and a heat pipe thermally connecting the first and second fin assemblies with the base. The first fin assembly has a first contacting face defining two grooves and the second assembly has a second contacting face facing to the first contacting face defining two grooves. The heat pipe includes an evaporation section thermally connecting with the base and the first and second fin assemblies, a first condensation section and a second condensation section respectively thermally engaging in the grooves of the first contacting face of the first fin assembly and the second contacting face of the second fin assembly.

### BACKGROUND OF THE INVENTION

1. Field of the Invention

The present invention relates to heat dissipation devices, and particularly to a heat dissipation device having a heat pipe for cooling an electronic component, such as an integrated circuit package.

2. Description of related art

During operation of an electronic device such as a computer central processing unit (CPU), a large amount of heat is often produced. The heat must be quickly removed from the CPU to prevent it from becoming unstable or being damaged. Typically, a heat dissipation device is attached to an outer surface of the CPU to absorb the heat from the CPU. The heat absorbed by the heat dissipation device is then dissipated to ambient air.

Conventionally, a heat dissipation device comprises a solid metal base attached to the CPU, and a plurality of fins arranged on the base. The base is intimately attached to the CPU thus allowing it to absorb the heat generated by the CPU. Most of the heat absorbed by the base is transferred firstly to the fins and then dissipates away from the fins. However, as electronics technology continues to advance, increasing amounts of heat are being generated by powerful state-of-the-art CPUs. As a result, many conventional heat dissipation devices are no longer able to effectively remove heat from these CPUs.

In order to overcome the above problems, one type of heat dissipation device used for the electronic devices includes a heat pipe for transferring heat from one part of the heat dissipation device to another part of the heat dissipation device. A heat pipe is a vacuum-sealed pipe that is filled with a phase changeable material, usually being a liquid, such as water, alcohol, acetone or the like, and has an inner wall thereof covered with a capillary configuration. As the electronic device heats up, a hot section (usually called an evaporation section) of the heat pipe, which is located close to the electronic device, also heats up. The liquid in the evaporation section of the heat pipe evaporates and the resultant vapor reaches a cool section (usually called a condensation section) of the heat pipe and condenses therein. Then the condensed liquid flows to the evaporation section along the capillary configuration of the heat pipe. This evaporation/condensation cycle repeats and since the heat pipe transfers heat so efficiently, the evaporation section is kept at or near the same temperature as the condensation section of the heat pipe. Correspondingly, heat-transfer capability of the heat dissipation device including such a heat pipe is greatly improved.

A heat dissipation device may incorporate a plurality of heat pipes. The heat dissipation device further comprises a base for contacting an electronic device and a plurality of fins arranged on the base. The base defines a plurality of grooves therein. The fins cooperatively define a plurality of through holes therein. Each heat pipe is generally U-shaped and has a substantially straight evaporation section received in a corresponding groove of the base, a straight condensation section received in a corresponding through hole of the fins. The heat generated by the electronic device is absorbed by the base, and transferred from the base to the fins via the heat pipes, and finally dissipated from the fins to ambient air. However, in order to improve heat dissipation efficiency of the heat dissipation device, the number of the heat pipes is increased, which accordingly increases the cost of the heat dissipation device.

What is needed, therefore, is a heat dissipation device which has a greater heat-transfer capability whilst remaining economical to produce. More specifically, the present invention is aimed to enhance the heat dissipation capability of the heat dissipation device without increasing the number of the heat pipes.

### SUMMARY OF THE INVENTION

A heat dissipation device with a heat pipe in accordance with a preferred embodiment of the present invention removes heat from an electronic device. The heat dissipation device with a heat pipe includes a base for thermally engaging with an electronic device, a first fin assembly and a second fin assembly arranged on the base, and a heat pipe thermally connecting the first and second fin assemblies with the base. The first fin assembly has a first contacting face defining two grooves and the second assembly has a second contacting face facing to the first contacting face and defining two grooves. The heat pipe includes an evaporation section located between the base and the first and second fin assemblies, a first condensation section and a second condensation section respectively thermally engaging in the grooves of the first contacting face of the first fin assembly and the second contacting face of the second fin assembly.

Other advantages and novel features of the present invention will become more apparent from the following detailed description when taken in conjunction with the accompanying drawings.

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views.

FIG. 1 is an exploded, isometric view of a heat dissipation device in accordance with a preferred embodiment of the present invention;

FIG. 2 is an assembled view of FIG. 1;

FIG. 3 is an exploded, isometric view of a heat dissipation device in accordance with a second embodiment of the present invention; and

FIG. 4 is an assembled view of FIG. 3.

### DETAILED DESCRIPTION OF THE INVENTION

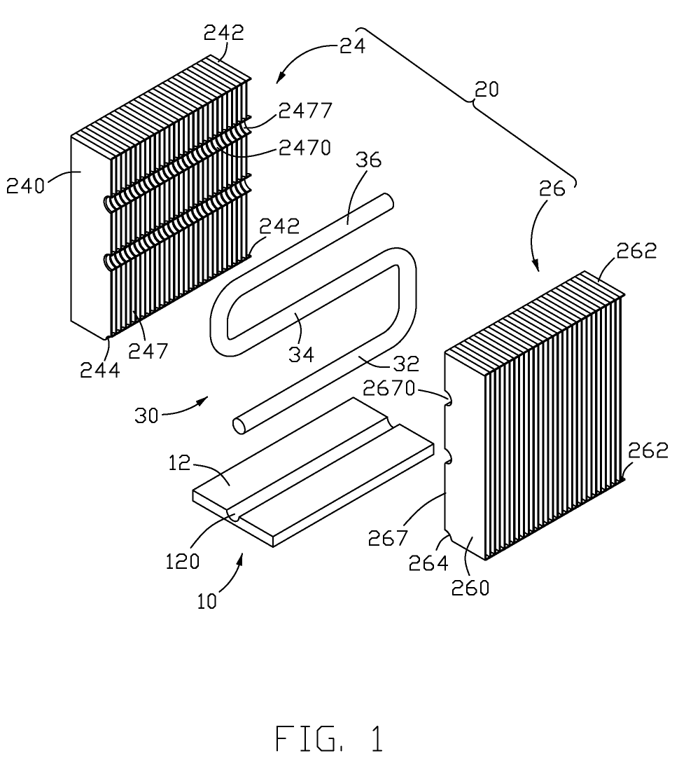

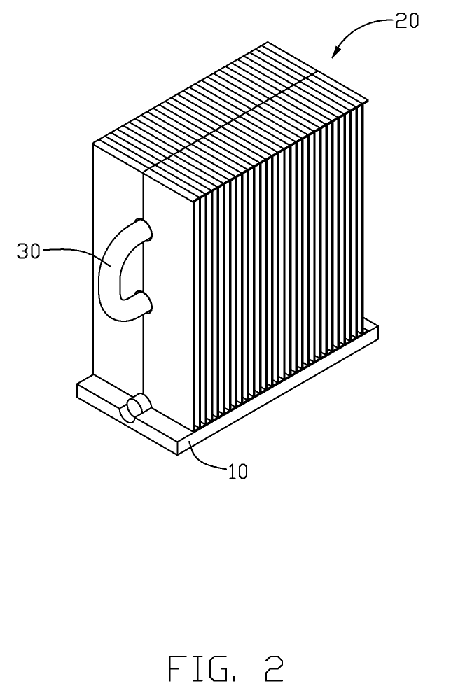

Referring to FIG. 1 and FIG. 2, a heat dissipation device of a preferred embodiment of the invention comprises a base 10, a heat sink 20 arranged on the base 10, a heat pipe 30 thermally connecting the base 10 and heat sink 20.

The base 10 is a substantially rectangular metal plate having good heat conductivity, and has a bottom face (not labeled) for contacting with an electronic device (not shown) on a printed circuit board (not shown) and a top face 12 on an opposite side to the bottom face. A groove 120 is defined in the base 10 at the top face 12 for receiving the heat pipe 30 therein.

The heat pipe 30 is bent to have an S-shaped configuration and comprises three coplanar horizontal sections, namely, an evaporation section 32, a first condensation section 34 and a second condensation section 36, according to their functions, respectively. The first and second condensation sections 34, 36 are located above the evaporation section 32. The first and second condensation sections 34, 36 are spaced from each other, and parallel to the evaporation section 32. In this embodiment, two free ends of the first condensation section 34 respectively interconnect adjacent ends of the evaporation section 32 and the second condensation section 36 via two perpendicular connecting sections (not labeled).

The heat sink 20 comprises a first fin assembly 24 and a second fin assembly 26 perpendicularly arranged on the base 10 and sandwiching the heat pipe 30 therebetween. The first fin assembly 24 comprises a plurality of parallel first fins 240 vertically standing on the base 10. Each first fin 240 is substantially rectangular and made from a thin metal sheet. Each first fin 240 defines two sets of flanges 242 extending perpendicularly from top and bottom edges of a body (not labeled) of the first fin 240 for spacing adjacent first fins 240. When the first fin assembly 24 is mounted on the base 10, the first fins 240 extend vertically upwardly from the base 10 and the flanges 242 of the bottom edges of the first fins 240 form a flat bottom face thermally contacting with the base 10. The first fin assembly 24 includes a contacting face 247 at a lateral side facing to the heat pipe 30. The first fin assembly 24 defines a pair of separate grooves 2470 in the contacting face 247 and a slot 244 at a bottom thereof corresponding to the groove 120 of the base 10. A flange 2477 perpendicularly extends from a lateral edge of each of the first fin 240 in a corresponding groove 2470. Corresponding flanges 2477 of the first fins 240 cooperatively form a contacting face for thermally contacting with a corresponding condensation section 34, 36 of the heat pipe 30 for enlarging contact area between the first fins 240 and the heat pipe 30.

The second fin assembly 26 has a configuration substantially similar to the first fin assembly 24 vertically standing on the base 10, and comprises a plurality of parallel second fins 260. Each second fin 260 defines two sets of flanges 262 extending perpendicularly from top and bottom edges of the second fin 260 for separating adjacent second fins 260. The second fin assembly 26 defines a contacting face 267 at a lateral side facing to the heat pipe 30. The second fin assembly 26 defines a pair of separate grooves 2670 in the contacting face 267 and a slot 264 at a bottom thereof corresponding to the groove 120 of the base 10. Flanges (not labeled) perpendicularly extend from the lateral edges of the second fins 260 in the grooves 2670 for enlarging the contacting area between the second fins 260 and the heat pipe 30. The grooves 2670 of the second fin assembly 26 are so defined that they cooperate with the corresponding grooves 2470 of the first fin assembly 24 to form two straight pipe-shaped passages thermally receiving the first and second condensation sections 34, 36 of the heat pipe 30 therein. The slot 264 of the second fin assembly 26 and the slot 244 of the first fin assembly 24 cooperate with the groove 120 of the base 10 to form a straight passage for receiving the evaporation section 32 of the heat pipe 30 therein. The first and second condensation sections 34, 36 of the heat pipe 30 are sandwiched between the first fin assembly 24 and the second fin assembly 26.

In use of the heat dissipation device of this embodiment of the invention, the base 10 absorbs heat from the electronic device to which the base 10 is attached. A portion of the heat in the base 10 is absorbed by the evaporation section 32 of the heat pipe 30 and is then transferred to the first fins 240 and the second fins 260 via the connecting sections and the first and second condensation sections 34, 36 of the heat pipe 30. The other portion of the heat in the base 10 is directly transferred to the first fins 240 and the second fins 260. The heat in the first and second fins 240, 260 is subsequently dissipated to ambient air.

In the present invention, since the heat pipe 30 has two spaced, parallel condensation sections 34, 36 engaging with a central portion and an upper portion of the first and second fins assemblies 24, 26, the heat pipe 30 of the present invention can function as well as two U-shaped heat pipes regarding the heat transferring capability. Thus, the present invention can enhance the heat dissipation capability of the heat dissipation device without increasing the number of the heat pipes. Furthermore, the heat pipe 30 is assembled in the heat dissipation device via the two fin assemblies 24, 26 horizontally sandwiching the heat pipe 30 therebetween instead of inserting a heat pipe through a single fin assembly as the conventional art did. Accordingly, assembling of the heat dissipation device according to the present invention can be simplified and cost thereof can be lowered, in comparison with a conventional heat dissipation device having the same heat dissipation capability.

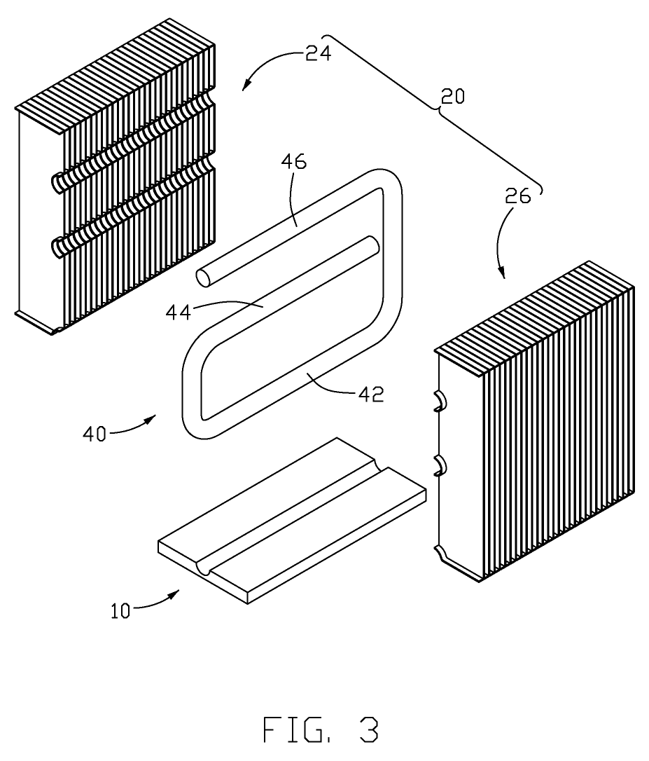

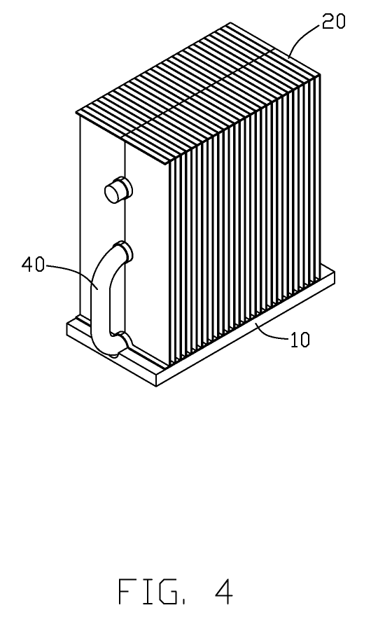

FIGS. 3-4 show a heat dissipation device of a second embodiment of the present invention. In this embodiment, the heat dissipation device comprises a base 10, a heat sink 20 comprising a first fin assembly 24 and a second fin assembly 26 arranged on the base 10. A heat pipe 40 thermally connects the base 10 and the heat sink 20, and the base 10 and the heat sink 20 have the same configuration as the first embodiment. However, in the second embodiment, the heat pipe 40 is bent to have a generally 6-shaped configuration and comprises three parallel and coplanar horizontal sections, namely, an evaporation section 42, a first condensation section 44 and a second condensation section 46, accordingly to their functions, respectively. Two free ends of the evaporation section 42 respectively interconnect adjacent ends of the first and second condensation sections 44, 46 via two perpendicular connecting sections (not labeled). The connecting section between the evaporation section 42 and the second condensation section 46 is longer than that between the evaporation section 42 and the first condensation section 44. In this embodiment, a single heat pipe still has two horizontal evaporation sections thermally engaging with the heat sink 20 to thereby increase the heat dissipation effectiveness without unduly increasing the cost of the heat dissipation device.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device with a heat pipe for removing heat from a heat generating device, the heat dissipation device comprising:
a base being made from one piece metal plate for thermally engaging with the heat generating electronic device;
a first fin assembly consisting of a plurality of first fins directly arranged on the base, the first assembly having a first contacting face defining two grooves;
a second fin assembly consisting of a plurality of second fins directly arranged on the base, the second assembly having a second contacting face facing to the first contacting face of the first fin assembly and defining two grooves therein; and
a heat pipe thermally connecting the first fins of the first fin assembly and the second fins of the second fin assembly with the base for transferring heat from the base to the first fins and second fins, the heat pipe comprising an evaporation section located between the base and the first fins and second fins, a first condensation section and a second condensation section respectively extending away the base and thermally engaging in the grooves of the first contacting face of the first fin assembly and the second contacting face of the second fin assembly.

2. The heat dissipation device with a heat pipe as described in claim 1, wherein the evaporation section and the first and second condensation sections of the heat pipe are parallel to each other.

3. The heat dissipation device with a heat pipe as described in claim 2 further comprising two connecting sections respectively interconnecting the first condensation section and the second condensation section and the first condensation section and the evaporation section.

4. The heat dissipation device with a heat pipe as described in claim 3, wherein the heat pipe has an S-shaped configuration.

5. The heat dissipation device with a heat pipe as described in claim 2 further comprising two connecting sections respectively interconnecting the evaporating section and the first condensation section and the evaporation section and the second condensation section, wherein the heat pipe has a generally 6-shaped configuration.

6. The heat dissipation device with a heat pipe as described in claim 1, wherein the first fins of the first fin assembly and the second fins of the second fin assembly extend flanges perpendicularly in the grooves from lateral edges thereof for enlarging contacting area between the first fins, the second fins and the heat pipe.

7. The heat dissipation device with a heat pipe as described in claim 1, wherein the first fins of the first fin assembly and the second fins of the second fin assembly extend flanges perpendicularly from bottom edges thereof and thermally contacting the base.

8. The heat dissipation device with a heat pipe as described in claim 1, wherein the base defines a groove at a top face thereof, and the first fin assembly and the second fin assembly define two slots cooperating with the groove of the base receiving the evaporation section of the heat pipe therein.

9. The heat dissipation device with a heat pipe as described in claim 1, wherein the first fins of the first fin assembly and the second fins of the second fin assembly are oriented perpendicularly to the base.

10. The heat dissipation device with a heat pipe as described in claim 1, wherein the first fin assembly and the second fin assembly are symmetrical about the heat pipe.

11. The heat dissipation device with a heat pipe as described in claim 1, wherein the first contacting face of the first fin assembly and the second contacting face of the second fin assembly are oriented perpendicularly to the base.

12. The heat dissipation device with a heat pipe as described in claim 1, wherein the evaporation section, the first condensation section and the second condensation are coplanar.

13. A heat dissipation device comprising:
a base having a bottom surface adapted for thermally connecting with a heat-generating electronic device;
first and second fin assemblies mounted on the base, each of the first and second fin assemblies having a top and a bottom and a contacting face between the top and the bottom, the contacting faces facing and connecting each other and cooperatively defining two transverse channels; and
a heat pipe having an evaporating section thermally connecting with the base and first and second condensation sections extending in the transverse channels and thermally connecting with the first and second fin assemblies.

14. The heat dissipation device as described in claim 13, wherein the heat pipe has a generally S-shaped configuration.

15. The heat dissipation device as described in claim 13, wherein the heat pipe has a generally 6-shaped configuration.
